(19) United States
(12) Patent Application Publication
(10) Pub. No.: US 2019/0154904 A1
(43) Pub. Date: May 23, 2019

(54) ARRAY SUBSTRATE AND FABRICATING METHOD THEREOF, FLEXIBLE DISPLAY PANEL, AND FLEXIBLE DISPLAY DEVICE

(71) Applicant: Wuhan China Star Optoelectronics Technology Co., Ltd., Wuhan (CN)

(72) Inventor: Guowei Zha, Shenzhen (CN)

(21) Appl. No.: 15/928,470

(22) Filed: Mar. 22, 2018

Related U.S. Application Data
(63) Continuation of application No. PCT/CN2018/072736, filed on Jan. 15, 2018.

(30) Foreign Application Priority Data
Nov. 21, 2017 (CN) 201711165143.8

(51) Int. Cl. F21V 8/00; H01L 27/12; G02F 1/1333; G02F 1/1335

(52) U.S. Cl. CPC G02B 6/0056; H01L 27/1218; H01L 27/1266; G02F 1/1368; G02B 6/004; G02B 6/0065; G02F 1/133528; G02F 1/133305

(57) ABSTRACT

The disclosure provides an array substrate including a flexible base substrate and a dielectric layer and a metal grid layer sequentially stacked on the surface of the flexible base substrate. The surface of the flexible base substrate away from the dielectric layer has a scattering structure. By sharing the flexible base substrate as the light guide plate and adding the metal wire grid to achieve the polarization and brightness enhancement functions, the disclosure reduces the thickness of the array substrate, effectively improves the problem of the bright color deviation caused by the flexible display panel during bending. The disclosure further provides a fabricating method of the array substrate, a flexible display panel, and a flexible display device.

### RELATED APPLICATIONS

This application is a continuation application of PCT Patent Application No. PCT/CN2018/072736, filed Jan. 15, 2018, which claims the priority benefit of Chinese Patent Application No. 201711165143.8, filed Nov. 21, 2017, which is herein incorporated by reference in its entirety.

### FIELD OF THE DISCLOSURE

The disclosure relates to the technical field of display panels, and in particular to an array substrate, a manufacturing method thereof, a flexible display panel, and a flexible display device.

### BACKGROUND

At present, Liquid Crystal Display (LCD) market has become a mainstream display. Flexible liquid crystal display device has also been widely developed, however, in the development of flexible liquid crystal display device is still faced with many technical problems. In the prior art, the light of the backlight needs to pass through a series of optical films and pass through an array substrate, a liquid crystal layer, and a color filter substrate in a thick liquid crystal cell structure, the longer propagation path during the planar or fixed curvature display can be customized through the viewing angle compensation diaphragm to solve the problem of uneven brightness under different viewing angles; however, in the case of flexible display, it is inevitable to face the bright chromatic aberration caused by a huge difference in the light propagation path under a completely different radius of curvature and under different visual angles.

Therefore, it is necessary to provide a flexible liquid crystal display panel which can well solve the problems such as bright chromatic aberration occurring under flexible display.

### SUMMARY

In view of this, the disclosure provides an array substrate and a manufacturing method thereof, a flexible display panel, and a flexible display. By sharing a flexible base substrate as a light guide plate and adding a metal wire grid to achieve polarization and brightness enhancement functions, the thickness of the array substrate is greatly reduced, and the flexible display panel effectively improves the problem of bright chromatic aberration caused by bending.

A first aspect of the disclosure provides an array substrate including a flexible base substrate and a dielectric layer and a metal grid layer sequentially stacked on the surface of the flexible base substrate. The surface of the flexible base substrate away from the dielectric layer has a scattering structure.

The metal grid layer includes metal wires arranged in parallel, the arrangement interval between the metal wires is of 20-500 nm, and a duty ratio of the metal wires is of 0.1-0.9. The material of the metal grid layer includes one or more of aluminum, silver, and gold.

The scattering structure is a mesh dot structure formed on or in the surface of the flexible base substrate. The mesh dot structure may include circular, square, V-shaped, or ladder-shaped concave and convex structure grooves.

The material of the dielectric layer includes one or more of silicon dioxide (SiO₂), silicon monoxide (SiO), magnesium oxide (MgO), silicon nitride (Si₃N₄), titanium dioxide (TiO₂), and tantalum pentoxide (Ta₂O₅).

The flexible base substrate is a light guide plate. The material of the flexible base substrate includes one or more of polyethylene, polypropylene, polystyrene, polylactic acid, polyethylene terephthalate, and polyimide.

According to the array substrate provided by the first aspect of the disclosure, the thickness of the array substrate is greatly reduced by sharing a flexible base substrate as a light guide plate and adding a metal wire grid to achieve polarization and brightness enhancement functions, thereby effectively improving improves the problem of the bright color deviation caused by the flexible display panel during bending.

A second aspect of the disclosure provides a flexible display panel including the array substrate according to the first aspect of the disclosure, a liquid crystal layer and a color filter substrate, the liquid crystal layer is sandwiched between the color filter substrate and the array substrate.

A third aspect of the disclosure provides a fabricating method of an array substrate, including the following steps:
providing a rigid substrate;
fabricating a flexible base substrate on the rigid substrate and forming a scattering structure in the flexible base substrate;
fabricating a dielectric layer on the flexible base substrate, wherein the scattering structure is located on a surface of the flexible base substrate away from the dielectric layer;
forming a metal layer on the dielectric layer and patterning the metal layer to form a metal wire grid layer;
sequentially fabricating a spacing layer and a thin film transistor driving layer on the metal wire grid layer; and
peeling off the rigid substrate to obtain an array substrate.

The step of forming a scattering structure in the flexible base substrate includes:
fabricating a convex and concave mesh dot structure on the rigid substrate, and then fabricating a flexible base substrate on the surface of the rigid substrate having a convex and concave mesh dot structure.

The metal grid layer includes a plurality of metal wires arranged in parallel, the arrangement interval between the metal wires is of 20-500 nm.

The rigid substrate includes a glass substrate, a silicon wafer, a metal or a rigid film.

The fabricating method of the array substrate provided by the third aspect of the disclosure has the advantages of simple and easy process, no need to remove the light guide plate, reduced the risk of panel breakage, cost saving of the process, and easy realization of industrialized production. Meanwhile, the fabricated product has greatly improved the color deviation of the brightness when the panel is under flexible display.

A fourth aspect of the disclosure further provides a flexible display, including the flexible display panel according to the second aspect of the disclosure and a backlight, the backlight providing a light source to the flexible display panel.

The advantages of the disclosure will be set forth in part in the description which follows, and in part will be obvious from the description, or may be learned by practice of the embodiments of the disclosure.

### BRIEF DESCRIPTION OF THE DRAWINGS

FIG. 1 is a schematic structural diagram of an array substrate 100 according to an embodiment of the disclosure;

FIG. 2 is a schematic structural diagram of an array substrate 200 according to another embodiment of the disclosure;

FIG. 3 is a schematic structural view of a flexible display panel 300 according to another embodiment of the disclosure; and

FIG. 4 is a flowchart of a fabricating process of an array substrate according to an embodiment of the disclosure.

### DETAILED DESCRIPTION OF PREFERRED EMBODIMENTS

The following is a preferred implementation of the embodiments of the disclosure. It should be noted that those skilled in the art may make various improvements and modifications without departing from the principle of the embodiments of the disclosure. These improvements and retouch are also considered as the protection scope of the embodiments of the disclosure.

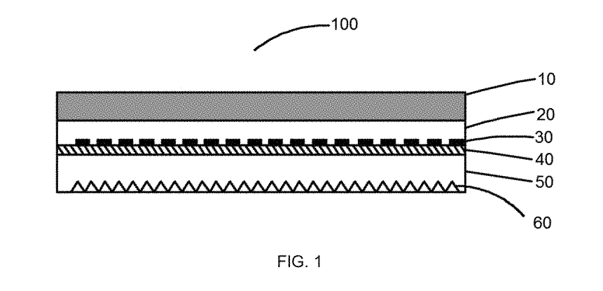

As shown in FIG. 1, an embodiment of the disclosure provides an array substrate 100, including a flexible base substrate 50 and a metal wire grid layer 40 and a dielectric layer 30 sequentially stacked on a surface of the flexible base substrate 50, a surface of the flexible base substrate 50 away from the dielectric layer 40 has a scattering structure 60. The array substrate 100 further includes a spacing layer 20 disposed on the metal wire grid layer 30 and away from the dielectric layer 40 and a thin film transistor (TFT) driving layer 10 located on the spacing layer 20.

In this embodiment, the metal wire grid layer 30 includes a plurality of metal wires arranged in parallel, and the arrangement interval between the metal wires is of 20-500 nm, a duty ratio of the metal wires to the dielectric layer is of 0.1-0.9, and the metal wires are periodically arranged on the dielectric layer 40. The cross-section of the metal wires may be rectangular or a variety of other conventional shapes. The metal wire grid layer 30 of the disclosure can be used for high-contrast polarization applications and can reflect almost all of the light of the electric field vector component vibrating in parallel with the metal wire grid layer, so that the light of the electric field vector component perpendicular to the metal wire grid layer almost completely passes through. Optionally, the material of the metal wire grid layer 30 has a larger imaginary part of refractive index, and specifically includes one or more of aluminum (Al), silver (Ag), and gold (Au). The arrangement direction of the metal wire grid layer 30 is required based on the specific needs of polarization decisions, the metal wire grid layer 30 provides the biasing function, while the trans electric (TE) polarized light parallel to the polarization direction of the wire is reflected and is recalculated into the light guide layer for recycling so as to improve backlight utilization efficiency.

In a specific embodiment of the disclosure, the material of the dielectric layer 30 includes one or more of SiO₂, SiO, MgO, Si₃N₄, TiO₂, and Ta₂O₅. The dielectric layer 30 is stacked between the flexible base substrate 50 and the metal wire grid layer 40. The dielectric layer 30 has excellent thermal stability, facilitates the fabrication of the metal wire grid layer 40 on the surface thereof, and the metal wire grid layer 40 between a stable structure; simultaneously, the dielectric layer 30 has good flexibility, conducive to achieve flexible bending, and having good light guiding properties, and the spread of light between the flexible base substrate 50 and the metal wire grid layer 40. The dielectric layer 30 has a thickness of 0.5-100 μm.

In a specific embodiment of the disclosure, the material of the flexible base substrate 50 includes one or more of polyethylene, polypropylene, polystyrene, polylactic acid, polyethylene terephthalate, and polyimide. The flexibility of a display panel can be effectively improved by adopting a flexible base substrate, which can prevent the risk of broken screen compared with a conventional rigid substrate (e.g. a glass substrate). Meanwhile, in the embodiment of the disclosure, in addition to the functions of the flexible base substrate described above, the flexible base substrate 50 also has a light guiding function and can be considered as a light guiding plate. The flexible base substrate 50 of the disclosure has good light guiding property and has highly reflectivity, non-light absorption, property of conventional light guide plate, and can replace the light guide plate of the traditional liquid crystal display panel. Therefore, compared with a conventional array substrate having a light guide plate and a base substrate with a relatively independent unit structure, in the present embodiment, the array substrate 100 is disposed with only a single flexible base substrate 50 having a light guiding function, that is, the flexible base substrate 50 has functions of flexible base substrate and light guide plate, and the array substrate 100 as a whole has a slimmer structure. The surface of the flexible base substrate 50 away from the dielectric layer 40 has a scattering structure 60. The scattering structure 60 is a mesh dot structure formed on the surface of the flexible base substrate 50 or inside the flexible base substrate 50. The mesh dot structure includes a circular, square, V-shaped or ladder-shaped concave and convex structure, and the mesh dot structure is not limited to the concave and convex structure, but also include other shapes conducive to light scattering structure. The scattering structure 60 can disrupt the total reflection of the interior of the flexible base substrate 50. When the light of the backlight passes through the flexible base substrate 50, the interior of the flexible base substrate 50 can be uniformly dispersed and uniformly emitted by the surface facing the dielectric layer 40. Meanwhile, the polarized light reflected by the metal wire grid layer 30 continues to circulate in the flexible base substrate 50 to improve the backlight utilization efficiency. In a specific embodiment of the disclosure, the thickness of the flexible base substrate may be of 0.2-0.5 mm, or 0.2-0.3 mm.

In the embodiment of the disclosure, the thin film transistor driving layer 10 is a conventional technical structure, and the disclosure is not limited thereto. The spacing layer 20 is configured to isolate the thin film transistor driving layer 10 and the metal wire grid layer 30. The spacing layer 20 can be a monolayer or multilayer structure of silicon nitride (SiNₓ) or silicon oxide (SiOₓ).

According to the array substrate 100 provided by the embodiment of the disclosure, the thickness of the array substrate is greatly reduced by adopting a flexible base substrate with good light guiding function and adding a metal wire grid to achieve polarization and brightness enhancement functions so as to reduce the difference in propagation paths of light caused by the overly long propagation paths at completely different radii of curvature; simultaneously, a scattering structure is added to the flexible base substrate to promote uniform light distribution and improve backlight utilization efficiency, thereby effectively improving the brightness chromatic aberration caused by the display panel during bending.

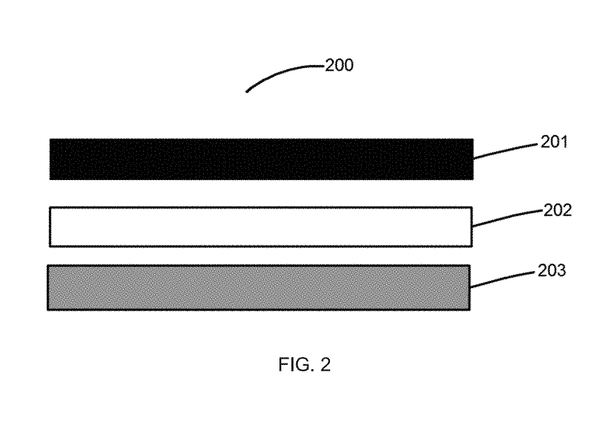

As shown in FIG. 2, the embodiment of the disclosure provides a flexible display panel 200 including a color filter substrate 201, a liquid crystal layer 202, and an array substrate 203 in order from top to bottom. The liquid crystal layer 202 is sandwiched between the color filter substrate 201 and the array substrate 203. The flexible display panel 200 has an array substrate 203 formed by a flexible base substrate having the properties of a light guide plate and adding a metal wire grid to achieve polarization and brightness enhancement functions, thereby effectively improving improves the problem of the bright color deviation caused by the flexible display panel during bending. The color filter substrate 201 and the liquid crystal layer 202 have a conventional technical structure, and the disclosure is not limited thereto.

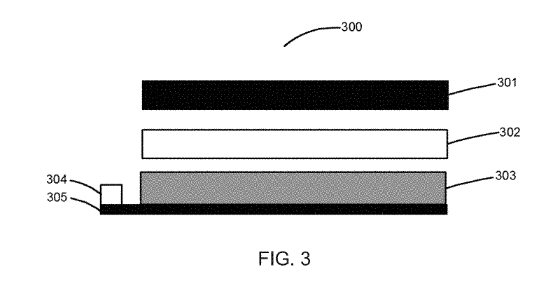

Another embodiment of the disclosure further provides a flexible display panel 300, as shown in FIG. 3, including a color filter substrate 301, a liquid crystal layer 302, and an array substrate 303 in order from top to bottom, and the liquid crystal layer 20 is sandwiched between the substrate 10 and the color filter array substrate 30. The flexible display panel 300 further includes a backlight 304 and a sealing frame 305, the backlight 304 may be a light emitting diode (LED) light, configured to provide a backlight to the flexible display panel 300; the sealing frame 305 is stacked on a surface of the array substrate 303 away from the liquid crystal layer 302, and between the sealing frame and the array substrate 303 further includes a reflective sheet, the reflective sheet can further enhance the backlight brightness of the flexible display panel 300, the material of the reflective sheet includes polyethylene terephthalate (PET) or modified PET.

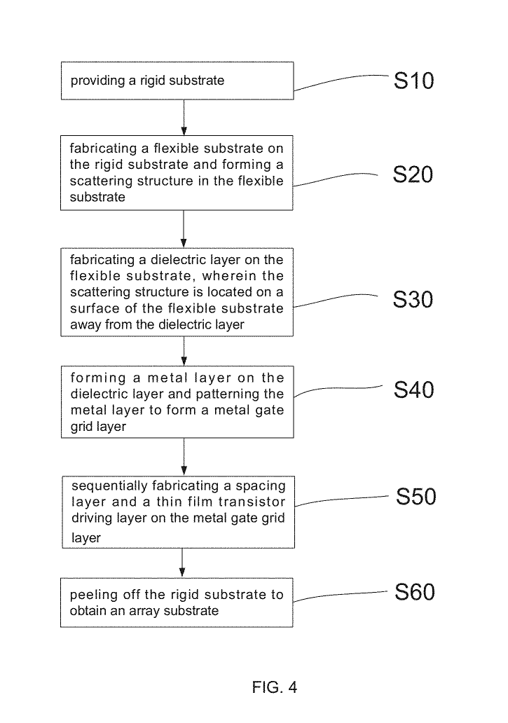

An embodiment of the disclosure further provides a fabricating method of an array substrate (as shown in FIG. 4), including the following steps:

S10: providing a rigid substrate;

S20: fabricating a flexible base substrate on the rigid substrate and forming a scattering structure in the flexible base substrate;

S30: fabricating a dielectric layer on the flexible base substrate, wherein the scattering structure is located on a surface of the flexible base substrate away from the dielectric layer;

S40: forming a metal layer on the dielectric layer and patterning the metal layer to form a metal wire grid layer;

S50: sequentially fabricating a spacing layer and a thin film transistor driving layer on the metal wire grid layer; and

S60: peeling off the rigid substrate to obtain an array substrate.

In the embodiment of the disclosure, in S10, the rigid substrate may be a glass substrate, a silicon wafer, a metal or a rigid film, and the rigid substrate needs to have high laser transmittance so as to facilitate the subsequent laser stripping process. In addition, in order to better bond the rigid substrate with the subsequent light-to-heat conversion layer and the flexible base substrate layer, the rigid substrate may be surface-treated to improve the surface energy of the rigid substrate. In the embodiment of the disclosure, the surface treatment method includes: cleaning a surface of the rigid substrate; and then performing plasma treatment on the cleaned surface of the rigid substrate by using an inert gas such as nitrogen, argon or the like. Through the processing, the surface energy of the rigid substrate can be increased, the adhesive force between the flexible base substrate and the rigid substrate can be increased, thereby avoiding the flexible base substrate being peeled off or detached from the rigid substrate in a subsequent process.

In the embodiment of the disclosure, in the step S20, a flexible base substrate is fabricated by coating on the rigid substrate, a plasma-enhanced chemical vapor deposition method or a magnetron sputtering method. The flexible base material includes one or more of polyethylene, polypropylene, polystyrene, polylactic acid, polyethylene terephthalate, and polyimide, and the flexible base substrate has a thickness of 0.2-0.5 mm, or 0.2-0.3 mm.

Specifically, the step of forming a polyimide (PI) flexible base substrate on the rigid substrate includes:

The aromatic tetracarboxylic dianhydride and the diamine monomer are respectively evaporated to form monomer vapor and mixed, and the mixed vapor is deposited on the rigid substrate; and then the dianhydride deposited on the rigid substrate and the diamine monomer is imidized to obtain a polyimide flexible base substrate. In the evaporation of the aromatic tetracarboxylic dianhydride and the diamine monomer, the aromatic tetracarboxylic dianhydride monomer has an evaporation temperature of 150° C. to 180° C., and an evaporation temperature of the diamine monomer is from 60° C. to 160° C. The imidization process may be performed in an infrared radiation oven, and the process is performed by heating under nitrogen protection at a rate of 0.5-3° C./min from room temperature to 320-385° C. for 1-3 hours and then naturally cooling to room temperature to obtain a PI flexible base substrate.

In the embodiment of the disclosure, in S20, forming a scattering structure in the flexible base substrate further includes fabricating a convex and concave mesh dot structure on the rigid substrate, and then fabricating a base substrate on the surface of the rigid substrate having convex and concave mesh dot structure. For example, a convex and concave mesh dot structure may be fabricated on the rigid substrate by injection molding or printing. The convex and concave mesh dot structure may be regularly arranged or arbitrarily arranged. The shape of the convex and concave mesh dot structures can be circular, square, V-shaped, trapezoidal or other shapes. Then, the flexible base substrate is continuously fabricated on the rigid substrate having the convex and concave mesh dot structure on the surface thereof.

In the embodiment of the disclosure, in S30, a dielectric layer is fabricated on the obtained flexible base substrate, and a dielectric layer is fabricated by plasma enhanced chemical vapor deposition or magnetron sputtering. The material of the dielectric layer includes SiO₂, SiO, MgO, Si₃N₄, TiO₂, and Ta₂O₅, and the dielectric layer has a thickness of 0.5-100 μm.

In the embodiment of the disclosure, in S40, a metal wire grid layer is fabricated on the dielectric layer obtained in S30, a metal layer is formed on the dielectric layer and the metal layer is patterned to form a metal wire grid layer; the metal wire grid layer is fabricated by a nano-imprinting technique, X-ray lithography, or lithography process. For example, according to the actual structure of the metal wire grid layer, the mold for nano-imprinting is selected and designed, and the metal wire grid layer is fabricated by the nano-imprinting technology. The metal wire grid layer includes a plurality of metal wires arranged in parallel, and the arrangement intervals between the metal wires may be of 20-500 nm.

In the embodiment of the disclosure, in S50, the spacing layer is fabricated on the metal wire grid layer by coating, plasma enhanced chemical vapor deposition or magnetron sputtering. The spacing layer may be a monolayer or multilayer structure of silicon nitride (SiNₓ) or silicon oxide (SiOₓ); then, the driving thin film transistor layer is further fabricated on the spacing layer, and the thin film transistor driving layer is fabricated by the conventional process, which is not particularly limited in the disclosure.

In the embodiment of the disclosure, in S60, an array substrate having a scattering structure is obtained by using a laser stripping process may be used to separate the rigid substrate from the flexible base substrate.

It should be noted that, those skilled in the art to which the disclosure pertains may also make changes and modifications to the above-mentioned embodiments based on the disclosure and description of the foregoing specification. Therefore, the disclosure is not limited to the specific embodiments disclosed and described above, and other equivalent modifications and alterations to the disclosure should also fall within the protection scope of the disclosure. In addition, although some specific terms are used in this specification, these terms are merely for convenience of description and do not limit the disclosure in any way.

What is claimed is:

1. An array substrate, comprising;
a flexible base substrate; and
a dielectric layer and a metal grid layer sequentially stacked on a surface of the flexible base substrate;
wherein a surface of the flexible base substrate away from the dielectric layer has a scattering structure.

2. The array substrate according to claim 1, wherein the metal wire grid layer comprises a plurality of metal wires arranged in parallel, an arrangement interval between the metal wires is of 20-500 nm, and a duty ratio of the metal wire is of 0.1-0.9.

3. The array substrate according to claim 1, wherein the scattering structure is a mesh dot structure formed on the surface of the flexible base substrate or inside the flexible base substrate.

4. The array substrate according to claim 1, wherein a material of the dielectric layer comprises one or more of SiO₂, SiO, MgO, Si₃N₄, TiO₂, and Ta₂O₅.

5. The array substrate according to claim 1, wherein the flexible base substrate is a light guide plate.

6. A flexible display panel, comprising:
an array substrate;
a liquid crystal layer;
and a color filter substrate;
wherein the array substrate comprises a flexible base substrate, and a dielectric layer and a metal wire grid layer sequentially stacked on a surface of the flexible base substrate, and a surface of the flexible base substrate away from the dielectric layer has a scattering structure;
wherein the liquid crystal layer is sandwiched between the color filter substrate and the array substrate.

7. The flexible display panel according to claim 6, wherein the metal grid layer comprises a plurality of metal wires arranged in parallel, an arrangement interval between the metal wires is of 20-500 nm, and a duty ratio of the metal wire is of 0.1-0.9.

8. The flexible display panel according to claim 6, wherein the scattering structure is a mesh dot structure formed on the surface of the flexible base substrate or inside the flexible base substrate.

9. The flexible display panel according to claim 6, wherein a material of the dielectric layer comprises one or more of SiO₂, SiO, MgO, Si₃N₄, TiO₂, and Ta₂O₅.

10. The flexible display panel according to claim 6, wherein the flexible base substrate is a light guide plate.

11. A manufacturing method of an array substrate, comprising the following steps:
providing a rigid substrate;
fabricating a flexible base substrate on the rigid substrate and forming a scattering structure in the flexible base substrate;
fabricating a dielectric layer on the flexible base substrate, wherein the scattering structure is located on a surface of the flexible base substrate away from the dielectric layer;
forming a metal layer on the dielectric layer and patterning the metal layer to form a metal wire grid layer;
sequentially fabricating a spacing layer and a thin film transistor driving layer on the metal wire grid layer; and
peeling off the rigid substrate to obtain an array substrate.

12. The method according to claim 11, wherein the step of forming a scattering structure in the flexible base substrate comprises:
fabricating a convex and concave mesh dot structure on the rigid substrate and then fabricating a flexible base substrate on the surface of the rigid substrate having a convex and concave mesh dot structure.

13. The method according to claim 11, wherein the metal grid layer comprises a plurality of metal wires arranged in parallel, the arrangement interval between the metal wires is of 20-500 nm.
